(19) United States
(12) Patent Application Publication
(10) Pub. No.: US 2018/0097055 A1
(43) Pub. Date: Apr. 5, 2018

(54) MICRO-TRANSFORMER WITH MAGNETIC FIELD CONFINEMENT AND MANUFACTURING METHOD OF THE SAME

(71) Applicant: STMicroelectronics S.r.l., Agrate Brianza (IT)

(72) Inventors: Elisabetta Pizzi, Limbiate (IT); Fabrizio Fausto Renzo Toia, Busto Arsizio (va) (IT); Marco Marchesi, Borgonovo Val Tidone (IT); Vincenzo Palumbo, Vimercate (IT)

(73) Assignee: STMicroelectronics S.r.l., Agrate Brianza (IT)

(21) Appl. No.: 15/454,096

(22) Filed: Mar. 9, 2017

(30) Foreign Application Priority Data
Sep. 30, 2016 (IT) 102016000098500

(51) Int. Cl. H01L 49/02; H01L 23/64; H01F 27/28; H01F 27/245; H01F 41/04; H01F 41/02

(52) U.S. Cl. CPC H01L 28/10; H01L 23/645; H01F 41/0233; H01F 27/245; H01F 41/041; H01F 27/2804

(57) ABSTRACT

A dielectric structure extends over the substrate and a transformer is integrated in the dielectric structure. The transformed includes a first winding in the dielectric layer at a first height and a second winding in the dielectric layer at a second height greater than the first height. The first and second windings are magnetically coupleable to one another. A magnetic element is positioned in alignment with the first and second windings. In one implementation, the magnetic element underlies the first winding in a position between the substrate and the first winding. In another implementation, the magnetic element overlies the second winding.

### PRIORITY CLAIM

This application claims the priority benefit of Italian Application for Patent No. 102016000098500, filed on Sep. 30, 2016, the disclosure of which is hereby incorporated by reference in its entirety.

### TECHNICAL FIELD

The present invention relates to an electronic component including a micro-transformer with magnetic field confinement and to a method for manufacturing said electronic component.

### BACKGROUND

Integrated transformers, of micrometric dimensions, are widely used in a wide range of fields of application, such as galvanic insulation, transfer of signals, and transfer of energy. For instance, in the field of galvanic insulation, integrated transformers are fundamental components in many modern electronic products that require exchange of data between two insulated electrical domains, for example, medical devices, controllers of motors, and communication devices. Commercially available systems typically use a plurality of coupling methods, which include inductive coupling based upon planar transformers, with a diameter of the windings of less than 1 mm. The reasons for these choices are multiple and include, for example, protection from voltages and currents.

A further field of application regards power conversion. Power converters are important components of battery-supplied portable electronic devices, and microtransformers are fundamental components thereof.

The miniaturization and integration of microtransformers is frequently in contrast with the high performance required by the aforementioned applications, and the development of high-performance, highly miniaturized, and integrated microtransformers today represents a challenge. The integration of high-quality magnetic cores using an effective manufacturing process represents a gap in the prior art. In fact, on account of the complexity of processing and definition of the materials that could be used, the choice of the magnetic materials employed in practice for the formation of the magnetic core is limited by the deposition processes available, such as sputtering or electroplating. However, these deposition processes may be used for depositing materials with limited thicknesses and homogeneity. Materials typically deposited with these methods include Ni—Fe. Other possibilities of fabrication regard the casting of ferrite or the assembly of magnetic ribbons (the latter being a non-integrated solution).

The inventors have detected the presence of a further problem of microtransformers according to the known art as regards their operation at frequencies of the order of megahertz or higher, i.e., at frequencies such that the magnetic losses become dominant on account of the parasitic currents (also known as “eddy currents” or “Foucault currents”). It has been found that, for high-frequency applications, it is likewise important to minimize the parasitic currents, for example, by making the magnetic core of a high-resistivity material and exploiting at the same time high-resistance substrates. There coexist the opposed needs of minimizing the effects of saturation by providing a sufficiently thick core, but at the same time of minimizing the thickness of the core to reduce costs.

Furthermore, to reduce the effects of parasitic currents in the substrate, the inventors have found, as has been said, that it is convenient to use substrates of highly resistive silicon. However, this type of substrate is not the substrate typically used in BCD (Bipolar-CMOS-DMOS) technology, which is a technology that integrates three different technologies: bipolar technology for precise analog functions; CMOS (Complementary Metal Oxide Semiconductor) technology for digital circuits; and DMOS (Double-Diffused Metal Oxide Semiconductor) technology for power and high-voltage components.

### SUMMARY

In an embodiment, a micro-integrated transformer is provided that will overcome the drawbacks mentioned above, and in particular that will enable reduction of the losses caused by the parasitic currents in the silicon substrate and, in general, increase of the efficiency of transfer by improving the magnetic coupling between the windings of the microtransformer. A method for manufacturing the micro-integrated transformer is also provided.

The present disclosure finds use in micro-integrated transformers in semiconductor structures or components which in particular include a substrate (e.g., a silicon substrate) over which one or more dielectric layers extend. The dielectric layers may house, in a per se known manner, metal layers (e.g., for routing of signals) and the mutually facing windings of the micro-transformer. According to one aspect of the present disclosure, a first layer of magnetic material is integrated between the silicon substrate and a bottom winding of the microtransformer, for providing a protective barrier or shield for the substrate from the magnetic field generated in use by the windings of the microtransformer. In other words, said shielding layer operates as element for confinement of the magnetic field generated in use by the bottom winding. A second layer of magnetic material extends over the microtransformer, above the top winding of the latter. Thus, the microtransformer (more precisely, the windings of the microtransformer) extends between the first and second layers of magnetic material.

According to further embodiments of the present disclosure, just one of the first and second layers of magnetic material may be present. The presence of the first or second layer of magnetic material, or of both of them, forms a low-reluctance path for the magnetic field generated by the respective windings and enables increase of the efficiency of transfer between the primary winding and the secondary winding, improving the magnetic coupling between them.

More in particular, the first layer of magnetic material concentrates the magnetic field generated by the windings of the microtransformer and limits the parasitic currents in the overlying silicon substrate, thus increasing the efficiency of the microtransformer. Both for the first layer and for the second layer of magnetic material, the increase in efficiency of the microtransformer is represented by the use and presence, in the path of the magnetic field lines, of a magnetic material with low reluctance if compared to air or silicon oxide, or to other non-magnetic materials.

However, since the loss due to parasitic currents also afflicts the first and second layers of magnetic material, according to a further aspect of the present disclosure, the layers of magnetic material include a plurality of magnetic sub-layers and insulating sub-layers alternating with one another in a laminated structure. The thickness of each of the magnetic layers of the laminated structure is chosen to be substantially equal to the skin depth δ of each of them. This embodiment enables interruption of the path of the currents in the respective layer of magnetic material.

According to a different embodiment, the first layer and/or second layer of magnetic material, having a thickness greater than the skin depth δ, may be sectioned in the direction of the thickness to form slices, which have a dimension (in this case, the width) equal to or less than the skin depth δ, separated from one another by dielectric layers. Also this embodiment enables interruption of the path of the currents in the respective layer of magnetic material.

### BRIEF DESCRIPTION OF THE DRAWINGS

For a better understanding of the invention, some embodiments thereof will now be described, purely by way of non-limiting example and with reference to the attached drawings, wherein:

FIG. 1 shows a system that comprises a galvanically insulated coupling module, in particular a transformer;

FIG. 2 illustrates, in lateral sectional view, a portion of an electronic component including a micro-integrated transformer according to one embodiment of the present disclosure;

FIG. 3A shows, in lateral sectional view, a structure for magnetic field confinement integrated in the electronic component of FIG. 2, according to one aspect of the present disclosure;

FIG. 3B shows, in top plan view, a structure for magnetic field confinement integrated in the electronic component of FIG. 2, according to a further aspect of the present disclosure;

FIG. 3C shows, in top plan view, a structure for magnetic field confinement integrated in the electronic component of FIG. 2, according to a further aspect of the present disclosure; and

FIGS. 4-12 illustrate, in lateral sectional views, steps for manufacturing the electronic component of FIG. 2.

### DETAILED DESCRIPTION

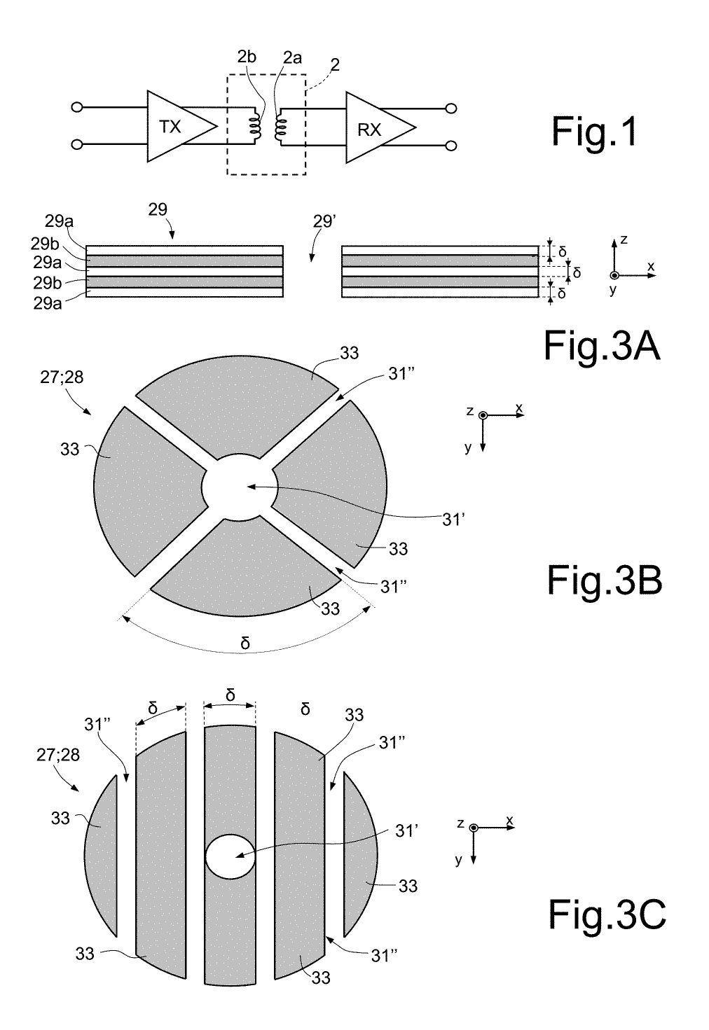

FIG. 1 is a schematic illustration of a system for transceiving an electrical signal based upon inductive coupling and configured so that a transmitter TX is galvanically insulated from a receiver RX by a transformer 2 (in particular, a micro-transformer). In this context, the term “micro-transformer” denotes a transformer produced according to the integrated-circuit manufacturing technology.

The system of FIG. 1 may be used for the transmission of electrical signals (e.g., data signals, signals of an impulse type, etc.) from the transmitter TX to the receiver RX. Furthermore, it is possible to transfer power through the transformer 2 or to use the transformer 2 for translation of a signal between two different voltage levels. In industrial applications, the system of FIG. 1 may likewise be used for high-voltage driving circuits, for communication and control systems, measurement systems, and test systems. Since the signals, of whatever type they may be, are transmitted through galvanic insulation, any type of conductive path between the transmitter TX and the receiver RX from which the transmitter TX is to be insulated is eliminated.

In use, the transmitter TX receives an input signal (to be transmitted) from a control circuitry, and supplies the input signal to a primary winding 2b. The receiver RX is coupled for receiving from the secondary winding 2a a signal corresponding to the input signal supplied to the primary winding 2b, and generates an output signal comprising a reconstituted input signal.

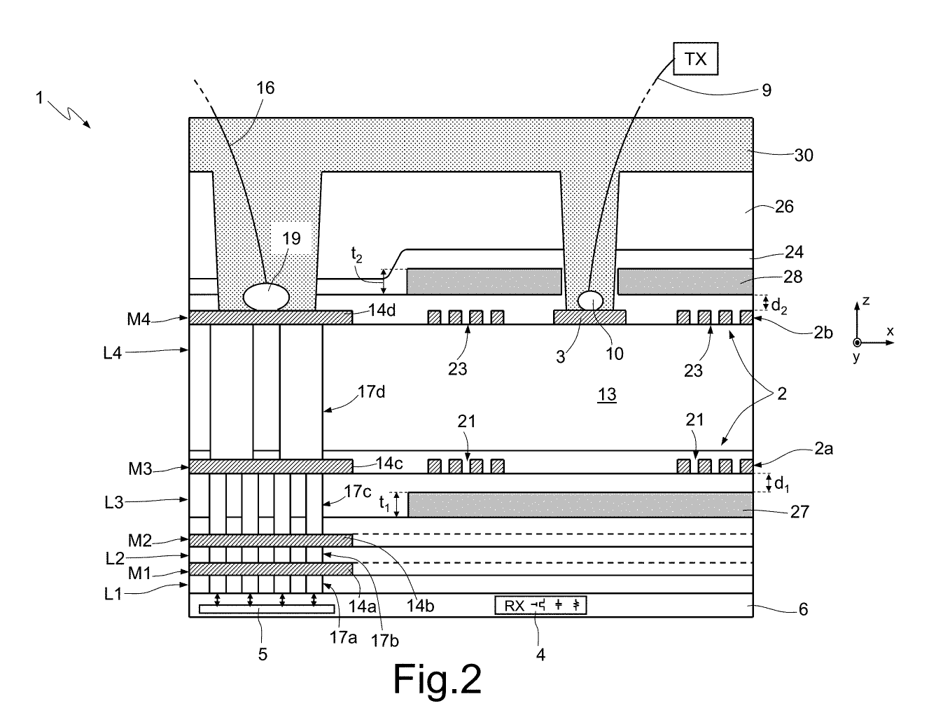

With reference to FIG. 2, illustrated therein, in lateral sectional view and in a triaxial reference system X, Y, Z, is a portion of an electronic device 1 (or electronic component) including the microtransformer 2 of an integrated type. The electronic device 1 likewise integrates a signal-receiver unit RX, according to one embodiment. According to the present disclosure, the transmitter TX and the receiver RX are interchangeable. Furthermore, the transmitter TX and the receiver RX may both be transceiving modules, configured to function in transmission or reception, as required.

The transformer 2 includes a bottom winding 2a (in this example, the secondary winding) and a top winding 2b (in this example, the primary winding), here represented purely by way of example as each having four turns designated by the references 21 and 23, respectively.

It is, however, evident that the number of turns may be other than four, and chosen as required, for example, in a number comprised between two and thirty. The bottom winding 2a and top winding 2b extend at a distance from one another along the axis Z, separated by one or more layers of dielectric material (e.g., silicon oxide) that forms a galvanic-insulation region 13.

An electrical-contact region 3, of metal material (e.g., copper), extends at the same metal level as the top winding 2b, inside the turns 23 thereof and is electrically coupled to the turns of the top winding 2b. The electrical-contact region 3 is likewise electrically coupled to a bonding wire 9 by a bonding region 10.

The microtransformer 2 functions as galvanic-insulation module and as interface for transfer of power between the transmitter TX, which is external to the device 1, and the receiver RX, which is integrated in a semiconductor body (substrate) 6 of the device 1, or vice versa.

The receiver RX includes, in a per se known manner and on the basis of the signal that it has to receive, electronic components/circuits designated as a whole by the references 4 and 5, which function, for example, at voltages in the range between 1 V and 40 V. The receiver RX is operatively coupled to the bottom winding 2a, to acquire from the bottom winding 2a the signal transmitted by the transmitter TX. The electrical components and/or circuits 4 may be located in the region overlying the microtransformer 2, as illustrated in FIG. 2, or else staggered with respect to the microtransformer 2.

The semiconductor body 6 (for example, including silicon) is, in particular, obtained in BCD (Bipolar-CMOS-DMOS) technology, which is a technology that integrates three different technologies: bipolar technology for precise analog functions; CMOS (Complementary Metal Oxide Semiconductor) technology for digital circuits; and DMOS (Double-Diffused Metal Oxide Semiconductor) technology for power and high-voltage components.

Extending over the semiconductor body 6 are one or more metal levels. In the embodiment of FIG. 2 four metal levels M1-M4 are illustrated, each including respective metal regions 14a-14d. The third metal level also includes the bottom winding 2a, and the fourth metal level M4 also includes the top winding 2b. Furthermore, in a way not shown in FIG. 2, the metal levels M1-M4 may include further metal regions.

According to an aspect of the present disclosure, in the dielectric region that extends between the bottom winding 2a and the substrate 6 electronic circuits and components may be formed, at least in part. In this case, said region comprised between the bottom winding 2a and the substrate 6 is an active-area region of the device 1.

According to a different embodiment, the dielectric region that extends between the bottom winding 2a and the substrate 6 does not comprise electronic components or circuits. In this case, the microtransformer 2 is formed alongside the active-area region of the device 1.

Extending between the third metal level M3 and the fourth metal level M4 is the galvanic-insulation layer 13, in the form of thick dielectric layer, having a thickness, along the Z axis, comprised between 1 μm and 30 μm, for example, 10 μm. The galvanic-insulation layer 13 is the layer that separates the bottom winding 2a from the top winding 2b of the transformer 2, and its thickness is chosen according to the voltage class required for galvanic insulation and such as to guarantee that class.

The metal region 14d of the fourth metal level M4 is exposed at a front side 1a of the device 1 (to form an external electrical contact pad). For this purpose, the metal region 14d is electrically coupled to a bonding wire 16 by a bonding region 19. The bonding wire 16 and the bonding region 19 are of conductive metal material, for example, gold.

Each metal level M2-M4 is electrically coupled to the bottom metal level M1-M3 by via levels L2-L4. A further via level L1 extends underneath the first metal level M1 to form an electrical contact towards the semiconductor body 6. The via levels L1-L4 include conductive through vias 17a-17d. The conductive vias 17a-17d are, for example, of metal material, such as tungsten or copper. Dielectric layers 20a-20c, made for example, of silicon oxide, extend between one metal level M1-M3 and the next, and between the first metal level M1 and the semiconductor body 6, as well as alongside each metal region belonging to a same metal level M1-M4.

The semiconductor body 6 may integrate a wide range of electrical and electronic components/circuits 5, which have specific functions that are not described in detail herein in so far as they do not form a subject of the present disclosure. Irrespective of the functions of said electronic circuits 5, conduction terminals thereof are electrically coupled with the outside of the device 1 via the metal regions 14a-14d and the conductive vias 17a-17c, for transmission/reception of electrical control signals thereof.

One or more insulation and passivation layers 24, 26 extend on the front side of the device 1. Furthermore, a resin layer 30 (for example, a layer of epoxy resin) covers the device 1 and forms part of the package (not illustrated in its entirety) of the device 1.

According to one aspect of the present disclosure, the device 1 further includes a first layer of magnetic material and a second layer of magnetic material (which are defined hereinafter also as “confinement layers”) 27, 28, designed to confine the magnetic field generated in use by the bottom winding 2a and the top winding 2b of the transformer 2.

The first and second confinement layers 27, 28 include, as has been said, magnetic material, in particular of an electrically conductive type, for example, an alloy including cobalt.

The first confinement layer 27 extends underneath the bottom winding 2a and is substantially arranged, in the view along the Z axis, underlying the bottom winding 2a. More in particular, the first confinement layer 27 extends within the via level L3, embedded in a layer of dielectric material. In one embodiment, the distance d₁, along the Z axis, between the first confinement layer 27 and the bottom winding 2a is comprised between 600 nm and 800 nm. The thickness t₁ of the first confinement layer 27, measured along the Z axis, is chosen so that, as a function the power of the signal to be transferred, there do not occur phenomena of saturation of the first confinement layer 27, thus enabling the transformer to work in linear regime. For instance, the thickness t₁ of the first confinement layer 27 is comprised between 200 nm and 1000 nm.

The second confinement layer 28 extends over the top winding 2b, and substantially arranged, in the view along the Z axis, overlying the top winding 2b. More in particular, the second confinement layer 28 extends over the fourth metal level M4 and is separated from the latter by a dielectric layer. Dielectric material likewise forms the layer 24 that covers the second confinement layer 28. In one embodiment, the distance d₂, along the Z axis, between the second confinement layer 28 and the top winding 2b is comprised between 600 nm and 800 nm. In general, this distance is chosen so that the excitation current, which flows in the winding 2b, will not generate a field such as to saturate the magnetic material having a thickness t₂. The thickness t₂ of the second confinement layer 28, measured along the Z axis, is chosen taking into consideration both the value of the excitation current of the winding 2b and the distance d₂, so that the resulting magnetic field may concatenate therewith, without saturating it, and thus keep the transformer operating in linear regime.

In top plan view, i.e., viewing the plane XY in the direction of the Z axis, the second confinement layer 28, the top winding 2b, the bottom winding 2a, and the first confinement layer 27 are arranged on top of one another, i.e., substantially aligned with each other along the Z axis.

The extension along the X axis of the first and second confinement layers 27, 28 is equal to or greater than the extension, along the X axis, of the top and bottom windings 2b, 2a. In particular, in top plan view, the first and second confinement layers 27, 28 have a circular shape with a diameter greater than the respective diameter of the top and bottom windings 2b, 2a (the latter, for example, being of a circular, quadrangular, or generically polygonal shape).

In one embodiment, at least the second confinement layer 28 has a central opening that bestows a doughnut shape thereon. Said central hole enables access to the electrical-contact region 3 by the bonding wire 9. It is evident that the conductive connection between the electrical-contact region 3 and the bonding region 10 may be obtained in some other way, so that the central opening of the second confinement layer 28 is not necessary. Furthermore, the inventors have found that the central region of the first and second confinement layers 27, 28 does not make a significant contribution in terms of improvement of the transfer efficiency of the integrated transformer (in fact, in this region the field lines are coming out). For this reason, removal of the magnetic material for formation of the central opening has no impact on the aforementioned advantages. Instead, since in some particular situations said central region could be biased in an undesired way, its removal is, in specific operating conditions, advantageous.

As mentioned previously, since the presence of parasitic currents (eddy currents or Foucault currents) also afflicts the first and second confinement layers 27, 28, according to a further aspect of the present disclosure both the first confinement layer 27 and the second confinement layer 28 have a stacked structure, or laminated structure, (e.g., the stack 29 of FIG. 3A) formed by a plurality of magnetic layers 29a and insulating layers 29b alternating with one another, and have a central opening 29′. The sum of the thicknesses of the magnetic layers 29a of the first and second confinement layers 27, 28 is equal to the thickness t₁, t₂ indicated previously for a single thick magnetic layer.

With reference to FIG. 3A, the thickness of each of the magnetic layers 29a of the first and second confinement layers 27, 28 is chosen to be substantially equal to or less than the skin depth δ.

The skin-depth parameter 6 is given by the following formula:

$$δ = \sqrt{\frac{2 ρ}{ωμ}}$$

where ρ is the electrical resistivity of each of the magnetic layers of the stack, w is the angular frequency (2πf) of the field (e.g., RF field) generated in use by the windings traversed by alternating current, and μ is the magnetic permeability of the magnetic material of each of the magnetic layers of the stack. For instance, in the range of frequencies f of interest (3 MHz-500 MHz), the skin depth δ is comprised between 1000 nm and 80 nm considering a magnetic material having values of ρ=140 Ωcm and μ=μ₀μᵣ, where μ₀ is the magnetic permeability of vacuum and μᵣ is the relative permeability of the magnetic material, for example, of the order of 10⁵.

Illustrated in greater detail in lateral sectional view in FIG. 3A, is the stack or laminated structure 29. The thickness along the Z axis of each of the magnetic layers 29a is, as has been said, equal to δ, whereas the thickness along the Z axis of each of the dielectric layers 29b is chosen at will according to the technological needs. Each layer 29a, 29b extends in a plane parallel to the lines of flux of the magnetic field generated by the respective top and bottom windings 2b, 2a. In other words, the magnetic layers 29a having a thickness equal to or less than δ cause an electrical discontinuity that acts against the circulation of parasitic currents therein.

FIG. 3B shows a top plan view, in the plane XY, of the first and second confinement layers 27, 28, according to an embodiment in which a layer of magnetic material is deposited and patterned by lithographic and etching steps. As may be seen more clearly in FIG. 3B, the confinement layer 27, 28, has a circular shape and has a central hole 31′ and cuts (or trenches) 31″ that extend throughout the thickness of the confinement layer 27, 28 and for the entire diameter, thus defining a plurality of wafers 33 (here, by way of example, four in number) electrically insulated from one another (a layer of dielectric may be deposited within the cuts 31″).

As an alternative to what is illustrated in FIG. 3B, the cuts 31″ may extend in respective mutually parallel directions, as may be seen in FIG. 3C.

In general, the cuts 31″ delimit wafers of magnetic material which have a width equal to or less than δ and generate an electrical discontinuity that acts against the circulation of the parasitic currents in the layers of magnetic material.

The laminated structure 29 of FIG. 3A or the patterned magnetic layer of FIG. 3B or FIG. 3C may be used for obtaining the first and second confinement layers 27, 28. As has been said previously, the central hole 29′, 31′ has, according to an aspect of the present disclosure, the function (in the second confinement layer 28) of enabling electrical access to the electrical-contact region 3, and consequently it may be omitted in the first confinement layer 27. However, the presence of a central hole 29′, 31′ (in the respective embodiments) both in the first confinement layer 27 and in the second confinement layer 28 may prove advantageous in given operating conditions, as explained previously.

The embodiments of FIGS. 3B and 3C are alternative to one another and alternative to the formation of the layers of FIG. 3A. However, it is possible to make the cuts 31″ of FIG. 3B or FIG. 3C in the laminated structure 29 of FIG. 3A in order to further improve reduction of the parasitic currents. Thus, each of the confinement layers 27 and 28 is structured so that one or more dimensions have an extension equal to or less than the skin depth δ.

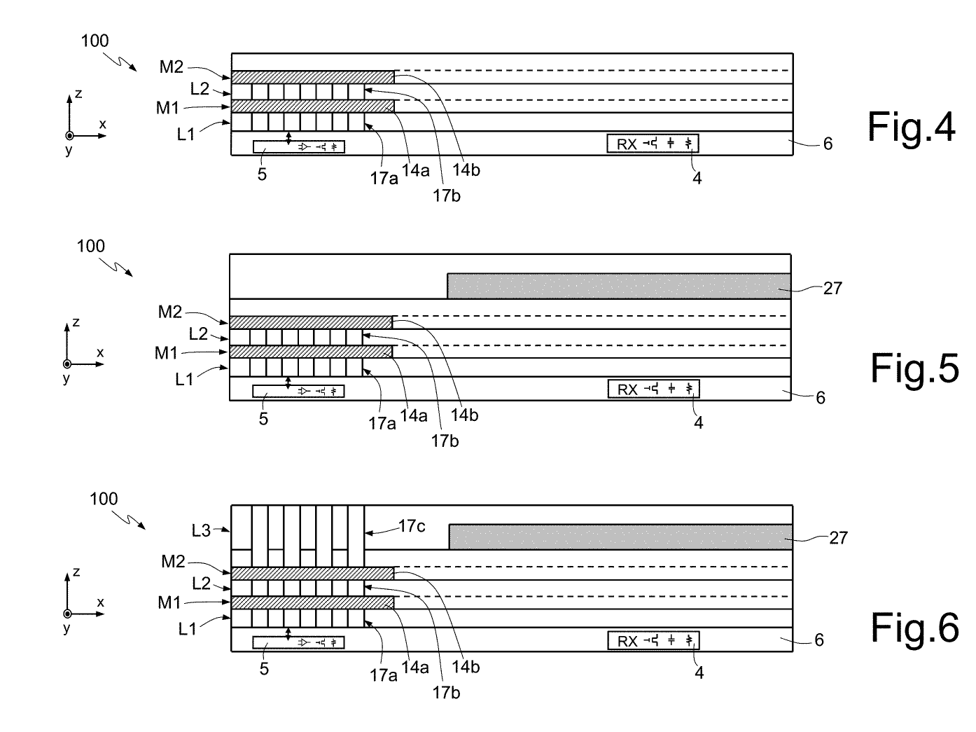

FIGS. 4-12 illustrate, in lateral sectional view, steps for manufacturing the device 1 of FIG. 2, according to an aspect of the present disclosure.

Illustrated in FIG. 4 is a wafer 100 in an initial manufacturing step, in which the semiconductor body, or substrate, 6 has already been patterned for integrating all the electrical and electronic functions required by the specific application, using any available micro-machining technology. Extending over the substrate, in a per se known manner, are the metallizations of the metal levels M1 and M2, and the through vias of the via levels L1 and L2 (in electrical connection with the metal regions 14a and 14b). Dielectric material, such as silicon oxide, extends alongside and over the metal regions 14a and 14b and the through vias 17a, 17b, in a per se known manner.

With reference to FIG. 5, the process continues with formation of the first confinement layer 27 by depositing on the dielectric that covers the metal region 14b a layer of magnetic material, in particular an alloy including cobalt. Deposition may be carried out, for example, using the PVD (Physical Vapor Deposition) technique. Then, a subsequent step of lithographic and chemical wet etching enables definition of the desired geometry for the first confinement layer 27. As has been said previously, the first confinement layer 27 may have a circular shape in top plan view and may optionally present cuts of the type illustrated in FIG. 3B. The first confinement layer 27 may be formed by depositing the magnetic material throughout the desired thickness t₁, or else by deposition of magnetic material alternating with deposition of dielectric material, to form the stack 29 illustrated in FIG. 3A, until the desired thickness t₁ is obtained. In this last case, after deposition on the stacked layers, the process continues with lithographic and etching steps, using appropriate chemical etching to define the desired shape of each of the magnetic/dielectric layers that form the stack.

The first confinement layer 27 is then coated with a layer of dielectric material, for example, silicon oxide.

Then (FIG. 6), the process continues with opening of through vias that from the front of the wafer 100 reach the metal region 14b, traversing the dielectric material previously deposited. Opening of the through vias is carried out in a per se known manner, by lithographic and chemical-etching steps. Then, a step of deposition of conductive material, for example, metal such as tungsten or copper, enables filling of said through vias, to form the conductive through vias 17c of the via level L3.

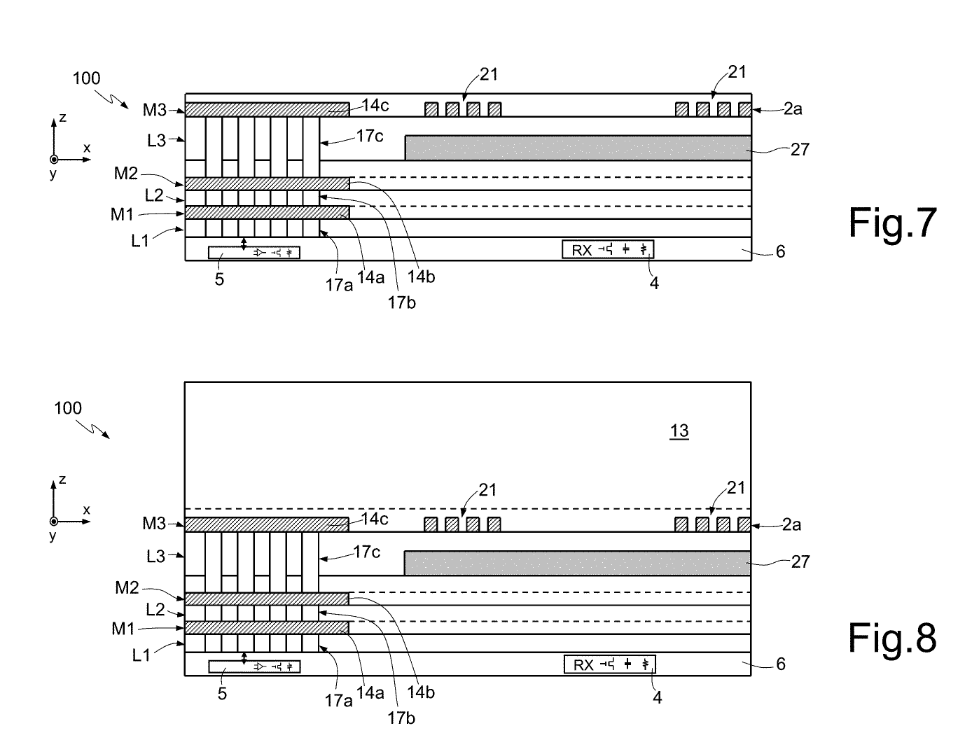

Next (FIG. 7), the process continues with formation, in a per se known manner, of the metal region 14c and of the bottom winding 2a. In one embodiment, the metal region 14c and the bottom winding 2a are formed simultaneously, with deposition on the front of the wafer 100 of a layer of conductive material, in particular metal, and a step of definition by etching, using an appropriate mask for simultaneous definition of the metal region 14c and of the bottom winding 2a. It is evident that, alternatively, the metal region 14c and the bottom winding 2a may also be formed or defined separately.

There is then deposited a layer of dielectric material on top of the metal region 14c and of the bottom winding 2a, as well as between the turns 21 of the bottom winding 2a, thus completing formation of the third metal level M3. More in particular, as illustrated in FIG. 8, the process continues with formation of one or more dielectric layers on the front of the wafer 100, to form the galvanic-insulation layer 13 For instance, the galvanic-insulation layer 13 is a deposited oxide (TEOS oxide), for example, silicon oxide (SiO₂). For this purpose, dielectric material is deposited between the turns 21 of the bottom winding 2a, and on top of, and between, the metal regions 12d, 14d. The galvanic-insulation layer 13 has a thickness of a few microns, for example, 10-15 μm, or some tens of microns, for example, 20-30 μm.

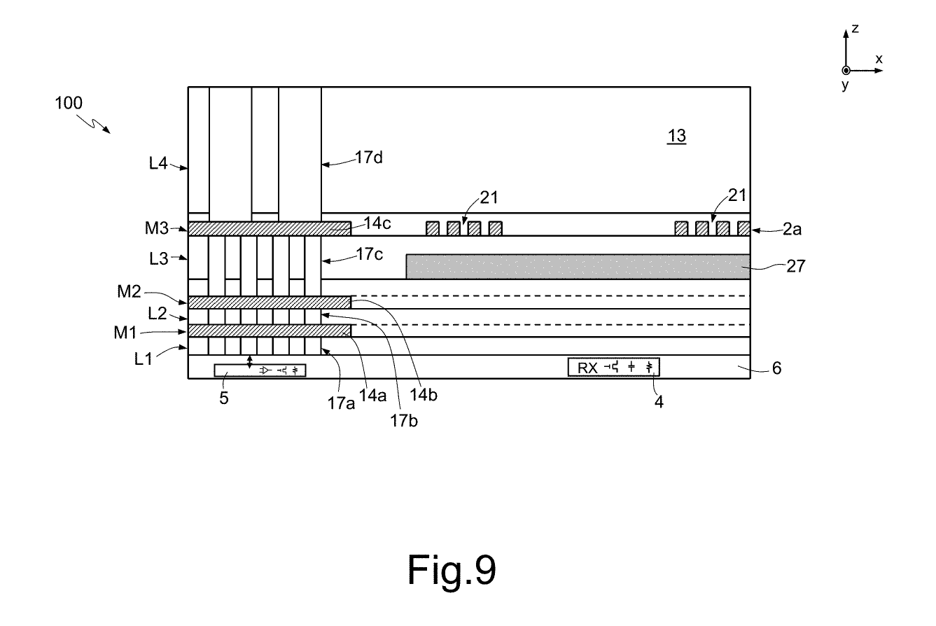

Then (FIG. 9), the process continues with a step of etching of the galvanic-insulation layer 13 in order to form through vias of the fourth via level L4. The through vias are formed by etching the front of the wafer 100 with plasma etching, after a prior masking step, for removing selectively the dielectric material in regions aligned, along the Z axis, with the underlying metal region 14c. The through vias 17d thus formed are then filled with conductive material, for example, metal material (e.g., tungsten or copper).

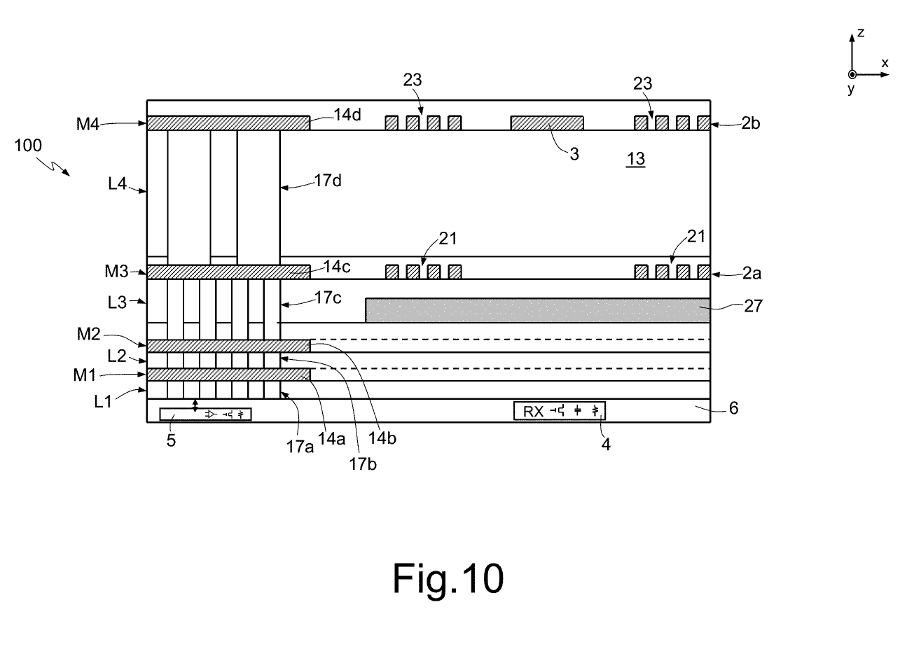

Then (FIG. 10), the process continues with formation of the top winding 2b, of the electrical-contact region 3 and of the metal region 14d. In one embodiment, the metal region 14d, the top winding 2b and the electrical-contact region 3 are formed simultaneously, with deposition on the front of the wafer 100 of a layer of conductive material, in particular metal (e.g., copper), and a step of definition by etching, using an appropriate mask for the simultaneous definition of the metal region 14d, of the top winding 2b and of the electrical-contact region 3. It is evident that, alternatively, the metal region 14d, the top winding 2b, and the electrical-contact region 3 may also be formed or defined separately. A dielectric layer 39 is deposited on the metal region 14d, between the turns 23 of the top winding 2b and on top of them.

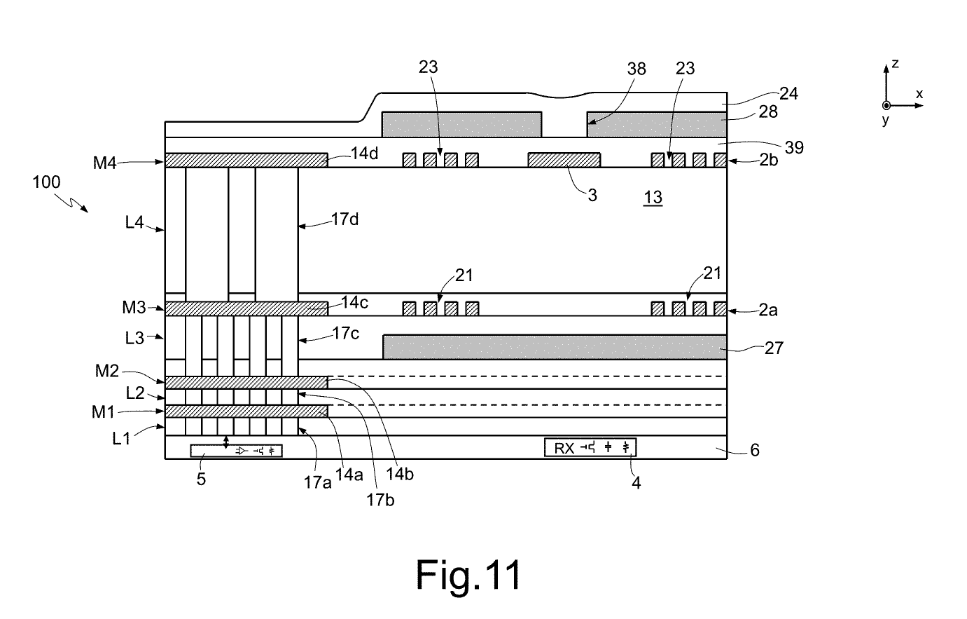

Then (FIG. 11), the process continues with formation of the second confinement layer 28 on the dielectric layer 39, in a way similar to what has already been described with reference to the first confinement layer 27, and will thus not be described any further here. The second confinement layer 28 may thus be a monolayer of magnetic material or else a multilayer of the type illustrated in FIG. 3A. More precisely, according to one embodiment, the second confinement layer 28 is defined, by lithographic and etching steps, for forming a through hole 38 of the type identified by the references 29′ and 31′ in FIGS. 3A-3C, according to the respective embodiments. Then, a layer of dielectric material 24 is deposited on the second confinement layer 28, for protection and insulation thereof.

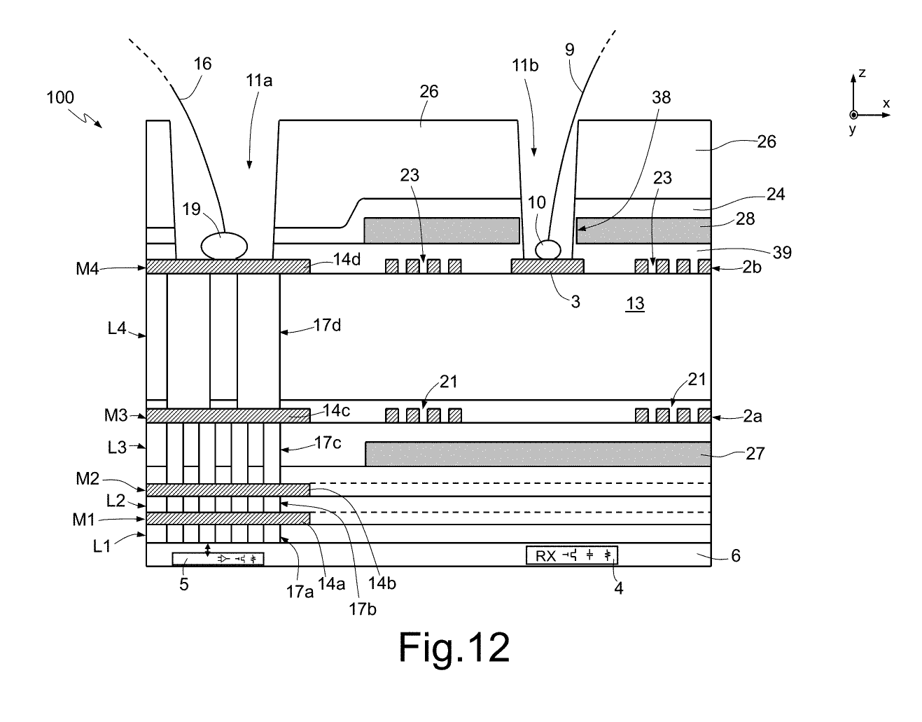

Next (FIG. 12), the process continues with steps of formation of a passivation layer 26, for example, silicon nitride, on the front side of the wafer 100. Then, the passivation layer 26 is removed in the metal region 14d and at the through hole 38. By a single etch, the process continues with removal of the underlying dielectric layers 24 and 39, as well as of the dielectric material deposited in the through hole 38, for exposing a surface portion of the metal region 14d and a surface region of the contact 3, to form the trenches 11a and 11b, respectively. The process then continues with steps of electrical connection by bonding of conductive wires, electrically coupling the bonding wire 16 with the metal region 14d, through the bonding region 19, and electrically coupling the bonding wire 9 with the electrical-contact region 3, through the trenches 11a, 11b.

Finally, a step of pouring of a resin, for example, epoxy resin, enables formation of the resin layer 30, to obtain the device 1 of FIG. 2.

Finally, it is evident that modifications and variations may be made to the present disclosure, without departing from the scope of the invention, as defined in the annexed claims.

In the embodiments of FIG. 2, the receiver RX is illustrated integrated in the device 1. It is, however, evident that, according to alternative embodiments, part of the receiver circuit RX, or the entire receiver circuit RX, may be provided outside the device 1, and operatively connected thereto (and, in particular, to the transformer 2) by connections of a known type (for example, by solder balls provided on the front of the device 1), or wire bonding, or some other electrical-connection technique still.

1. An electronic component, comprising:
a substrate;
a dielectric structure extending over the substrate;
a transformer integrated in said dielectric structure and comprising a first winding in the dielectric structure at a first height, and a second winding in the dielectric structure at a second height greater than the first height, said first and second windings being magnetically coupleable to one another; and
at least one of the following:
a first magnetic element underlying the first winding and positioned between the substrate and the first winding; and
a second magnetic element overlying the second winding.

2. The electronic component according to claim 1, wherein said at least one of the first magnetic element and second magnetic element consists of a single layer of magnetic material.

3. The electronic component according to claim 2, wherein said at least one of the first magnetic element and second magnetic element includes a central through opening formed in a centroidal region of said at least one of the first magnetic element and second magnetic element.

4. The electronic component according to claim 3, further including a trench that extends through the central through opening for making an electrical connection to one of the first winding and second winding.

5. The electronic component according to claim 1, wherein said at least one of the first magnetic element and second magnetic element comprises a laminated structure including plural layers of magnetic material arranged between layers of dielectric material to provide for an electrical discontinuity that acts against the circulation of parasitic currents said at least one of the first and second magnetic elements.

6. The electronic component according to claim 5, wherein the plural layers of magnetic material and the layers of dielectric material of said laminated structure each lie in a respective plane that is parallel a plane of said at least one of the first and second windings.

7. The electronic component according to claim 6, wherein each of said plural layers of magnetic material has a thickness, in a direction orthogonal to the plane in which the layer of magnetic material lies, that is equal to or less than a skin depth.

8. The electronic component according to claim 5, wherein the plural layers of magnetic material and the layers of dielectric material of said laminated structure each lie in a respective plane that is orthogonal to a plane of the at least one of the first and second windings.

9. The electronic component according to claim 8, wherein each of said plural layers of magnetic material has a thickness, in a direction orthogonal to the plane in which the layer of magnetic material lies, that is equal to or less than a skin depth.

10. The electronic component according to claim 5, wherein said at least one of the first magnetic element and second magnetic element includes a central through opening formed in a centroidal region of said at least one of the first magnetic element and second magnetic element.

11. The electronic component according to claim 10, further including a trench that extends through the central through opening for making an electrical connection to one of the first winding and second winding.

12. The electronic component according to claim 1, wherein said at least one of the first magnetic element and the second magnetic element includes a plurality of dielectric trenches structured for generating an electrical discontinuity to act against a circulation of parasitic currents in said at least one of the first and second magnetic elements.

13. A method for manufacturing an electronic component, comprising the steps of:
forming a dielectric structure on a substrate;
integrating a transformer in the dielectric structure, wherein integrating comprises:
forming a first winding in the dielectric structure at a first height,
forming a second winding in the dielectric structure at a second height, greater than the first height, so that said first and second windings are magnetically coupleable to one another, and
forming at least one of the following:
a first magnetic element underlying the first winding and positioned between the substrate and the first winding; and
a second magnetic element overlying the second winding.

14. The method according to claim 13, wherein the step of forming at least one of the first magnetic element and second magnetic element comprises depositing and defining a single layer of magnetic material.

15. The method according to claim 14, further comprising the step of forming a central through opening in a centroidal region of said at least one of the first magnetic element and second magnetic element.

16. The method according to claim 15, further comprising the step of forming a path for electrical access to one of the first winding and second winding through the central through opening.

17. The method according to claim 13, wherein the step of forming said at least one first magnetic element and second magnetic element comprises forming a laminated structure including alternating layers of magnetic material and dielectric material to provide an electrical discontinuity that acts against the circulation of parasitic currents in said at least one first and second magnetic elements.

18. The method according to claim 17, wherein the plural layers of magnetic material and the layers of dielectric material of said laminated structure each lie in a respective plane that is parallel a plane of said at least one of the first and second windings.

19. The method according to claim 18, wherein each of said plural layers of magnetic material has a thickness, in a direction orthogonal to the plane in which the layer of magnetic material lies, that is equal to or less than a skin depth.

20. The method according to claim 17, wherein the plural layers of magnetic material and the layers of dielectric material of said laminated structure each lie in a respective plane that is orthogonal to a plane of the at least one of the first and second windings.

21. The method according to claim 20, wherein each of said plural layers of magnetic material has a thickness, in a direction orthogonal to the plane in which the layer of magnetic material lies, that is equal to or less than a skin depth.

22. The method according to claim 13, wherein forming said at least one first magnetic element and second magnetic element comprises:
depositing magnetic material, and
forming a plurality of dielectric trenches in said deposited magnetic material, said plurality of dielectric trenches structured to provide an electrical discontinuity such as to act against the circulation of parasitic currents in the deposited magnetic material.

23. The method according to claim 22, further comprising the step of forming a central through opening in a centroidal region of said at least one of the first magnetic element and second magnetic element.

24. The method according to claim 23, further comprising the step of forming a path for electrical access to one of the first winding and second winding through the central through opening.
